(19) United States
(12) Patent Application Publication
(10) Pub. No.: US 2020/0329593 A1
(43) Pub. Date: Oct. 15, 2020

(54) ELECTROMAGNETIC INTERFERENCE (EMI) SHIELD

(71) Applicant: 3M INNOVATIVE PROPERTIES COMPANY, St. Paul, MN (US)

(72) Inventor: Zulfiqar A. Khan, Woodbury, MN (US)

(21) Appl. No.: 16/310,222

(22) PCT Filed: Jun. 27, 2017
(86) PCT No.: PCT/US2017/039403

§ 371 Date: Dec. 14, 2018

Related U.S. Application Data
(60) Provisional application No. 62/356,715, filed on Jun. 30, 2016.

(51) Int. Cl. H05K 9/00; H05K 1/14; H05K 1/18

(52) U.S. Cl. CPC H05K 9/0026; H05K 1/14; H05K 9/0073; H05K 9/0032; H05K 1/181

(57) ABSTRACT

Electromagnetic interference (EMI) shields are provided to be placed on and cover an electronic component. The EMI shields at least partially surround the electronic component, and include an undulated edge. In some cases, an EMI absorbing material is placed along the undulated edge.

### TECHNICAL FIELD

The present disclosure relates to electromagnetic interference (EMI) shields including an undulated edge and methods of making and using the same.

### BACKGROUND

Electronic systems employ various methods to control electromagnetic interference (EMI) or noise arising from internal and/or external circuits and components. Among these methods, metallic shields are commonly used to enclose a particular device or component or even an entire system for protection against an external EMI or to prevent an EMI generated internally radiating from the system.

### SUMMARY

Briefly, in one aspect, the present disclosure describes an electromagnetic interference (EMI) shield configured to be placed on and cover an electronic component mounted on a circuit board. The EMI shield includes an electrically conductive fence configured to at least partially surround the electronic component, and an electrically conductive lid attached to a first edge of the fence. The fence has an undulated edge extending along at least a portion of a second edge of the fence opposite the first edge.

In another aspect, the present disclosure describes an electromagnetic interference (EMI) shield configured to be mounted on a circuit board. The shield includes an undulated edge having a first edge portion and a different second edge portion, such that when the shield is mounted on a circuit board, at least the first edge portion of the undulated edge is spaced apart from the circuit board. The first and second edge portions are arranged along a length of the second edge portion.

In another aspect, the present disclosure describes an electromagnetic interference (EMI) shield configured to be placed on and cover an electronic component mounted on a circuit board. The shield includes a first shield portion configured to attenuate an electromagnetic field primarily by reflection, and a second shield portion configured to attenuate an electromagnetic field primarily by absorption. The first and second shield portions define an undulated interface therebetween.

In another aspect, the present disclosure describes a shielded circuit board system including a circuit board, and an electronic component mounted on the circuit board and electrically connected to an electrically conductive first signal trace of the circuit board. An electromagnetic interference (EMI) shield is placed on and covers the electronic component. The first signal trace crosses under an edge of the shield and on each side of the shield to define an overlap region therebetween, a separation between the edge of the shield and the first signal trace being non-uniform across the overlap region.

In another aspect, the present disclosure describes a shielded cable extending longitudinally along a length of the cable between first and second ends of the cable. The shielded cable includes one or more conductors extending along the length of the cable between the first and second ends, and at least one shield extending along the length of the cable from the first end toward the second end. The shield includes a first edge at least partially surrounding the one or more conductors at the first end. The first edge is regularly undulated along a length of the first edge.

In yet another aspect, the present disclosure describes a shielded electrical connector including one or more electrical conductors extending between a first end and a second end. An electromagnetic interference (EMI) shield includes a first undulated edge adjacent to the first end of the electrical conductors and a second undulated edge adjacent to the second end of the electrical conductors. The EMI shield at least partially surrounds the electrical conductors to provide EMI protection.

Various unexpected results and advantages are obtained in exemplary embodiments of the disclosure. One such advantage of exemplary embodiments of the present disclosure is that an undulated edge of an EMI shield can effectively reducing an edge current induced by an electromagnetic field, thereby improving effectiveness of EMI protection. An EMI absorbing material can be disposed on and along the undulated edges to further reduce the induced current.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein

### BRIEF DESCRIPTION OF THE DRAWINGS

The disclosure may be more completely understood in consideration of the following detailed description of various embodiments of the disclosure in connection with the accompanying figures, in which:

FIG. 1 is a side perspective view of a circuit board.

FIG. 2A is a side perspective view of an EMI shield mounted on the circuit board of FIG. 1.

FIG. 2B is a cross-sectional view of the EMI shield of FIG. 2A.

FIG. 2C is a side perspective view of another EMI shield including a layer of EMI absorbing material.

FIG. 3A is side perspective view of an EMI shield, according to one embodiment.

FIG. 3B is a cross-sectional view of the EMI shield of FIG. 3A.

FIG. 4A is side perspective view of an EMI shield, according to another embodiment.

FIG. 4B is a cross-sectional view of the EMI shield of FIG. 4A.

FIG. 5 is a cross-sectional view of an EMI shield, according to another embodiment.

FIG. 6A is a side view of a shielded cable, according to one embodiment.

FIG. 6B is a cross-sectional view of the shielded cable of FIG. 6A.

FIG. 6C is a cross-sectional view of the shielded cable of FIG. 6A.

FIG. 7 is a side view of a shielded connector, according to one embodiment.

FIG. 8A illustrates induced voltage as a function of frequency for a PCB without shielding, and Comparative Examples C1 and C2.

FIG. 8B illustrates induced voltage as a function of frequency for Comparative Examples C1 and C2, and Example 1.

FIG. 8C illustrates induced voltage as a function of frequency for Comparative Example C1, and Examples 1 and 2.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

Various exemplary embodiments of the disclosure will now be described with particular reference to the Drawings. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

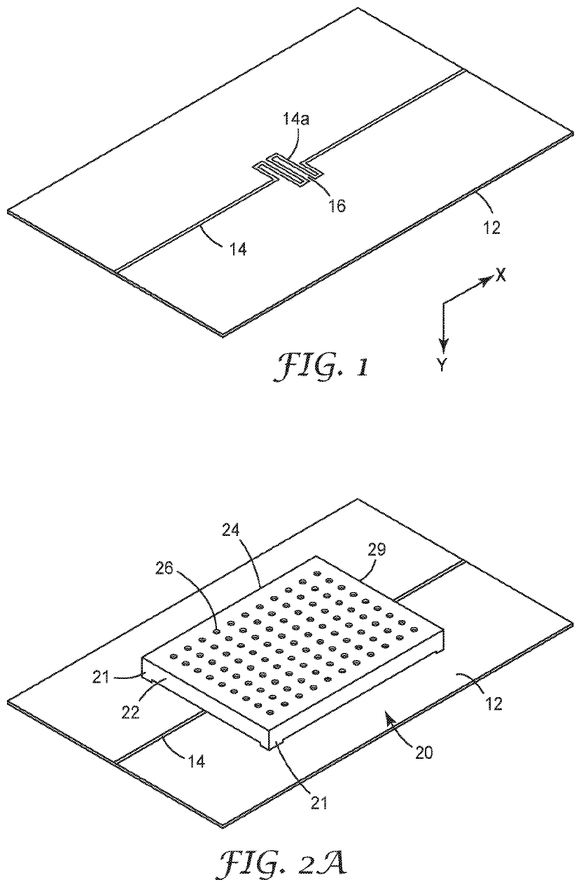

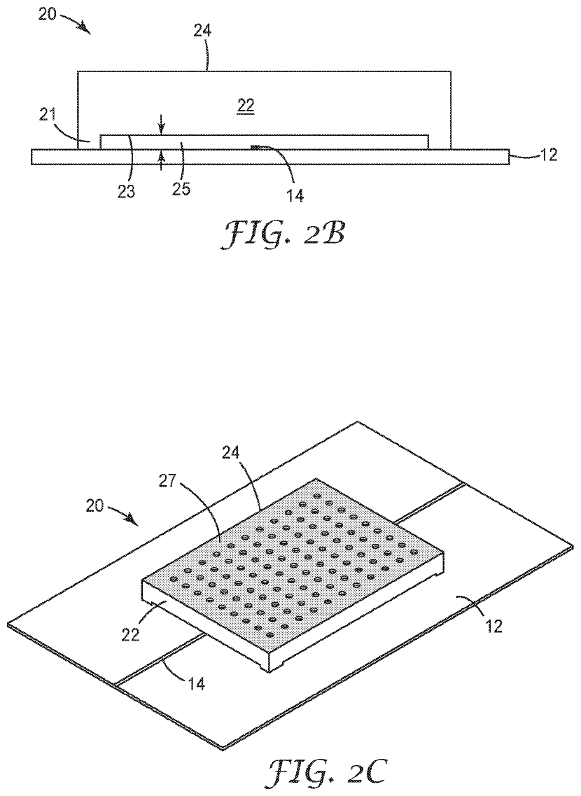

Metallic shields are commonly used to enclose at least a portion of a circuit board such as, for example, printed circuit board (PCB) for protection against external EMI or to prevent an EMI generated internally radiating from the system. The metallic shields may become ineffective when a PCB trace or a wire, already exposed to EMI radiation, penetrates the metallic shields. In practice, a circuit board may have one or more penetrating wires or traces across an edge of the metallic shields to electrically connect components enclosed by the metallic shield and other components outside the metallic shield. The shielding effectiveness of metallic shields may become unreliable in such scenarios. To enhance effectiveness of the metallic shields, EMI absorbers are commonly employed. This is further explained by FIGS. 1 and 2A-C below.

FIG. 1 is schematic view of a circuit board 12 with an electrical trace 14 routed on a substrate along the x axis from one end to another end. The circuit board 12 can be, for example, a printed circuit board (PCB). The electrical trace 14 has trace portions 14a that run substantially in parallel with gaps 16 therebetween where an electronic device/component can be connected. In the presence of an electromagnetic field such as, for example, an external EMI propagating towards the PCB 12 as a plane wave and impinging upon the PCB at a normal incidence angle along the y axis, a voltage might be induced on the trace portions 14a with the gaps 16.

In FIG. 2A, a metallic shield 20 is disposed on the circuit board 12 to at least partially enclose the trace portions 14a of the electrical trace 14 of FIG. 1. The metallic shield 20 is provided to protect the trace portions 14a and/or other components connected to the trace portions 14a from the external EMI by attenuating an electromagnetic field primarily by reflection. The metallic shield 20 has corners 21 that can be grounded to the PCB 12, a fence (e.g., sides 22 and 29) connecting to the corners 21, a top lid 24 attached to the fence. The lid 24 include ventilation holes 26. The electrical trace 14 enters the metallic shield 20 from one side 22 and exits on another side 29. As shown in FIG. 2B, the side 22 has a bottom edge 23 that defines a gap 25 with respect to the PCB 12. The electrical trace 14 can fit through the gap 25 without touching the bottom edge 23 of the shield 20. The gap 25 may have a suitable dimension that is greater than the thickness of the electrical trace 14. In some embodiments, the electrical trace 14 may have a thickness of, for example, several microns or more such as in the range of about 10 to about 100 microns. The part of the electrical trace 14 outside the metallic shield 20 might be still exposed to the external EMI and a current induced on the trace 14 can still enter the space enclosed by the metallic shield 20 conductively via the trace 14. The bottom edge 23 is straight. A straight edge like the bottom edge 23 may introduce a discontinuity to the signal and an EMI-induced currents flowing on the penetrating wire or trace may potentially lead to high edge currents on the metallic shield. See Comparative Example C1 to be discussed further below.

In FIG. 2C, a layer of absorbing material 27 is disposed on the lid 24 of the metallic shield 20 to absorb possible EMI. See Comparative Example C2 to be discussed further below. The layer 27 can include any suitable absorbing materials that are capable of attenuate an electromagnetic field by absorption. The absorbing materials may include, for example, dielectric absorbing materials, magnetic absorbing materials, etc. Exemplary absorbing materials include, for example, Carbon Black, Copper Oxide, Ferrites, NiFe composites, etc.

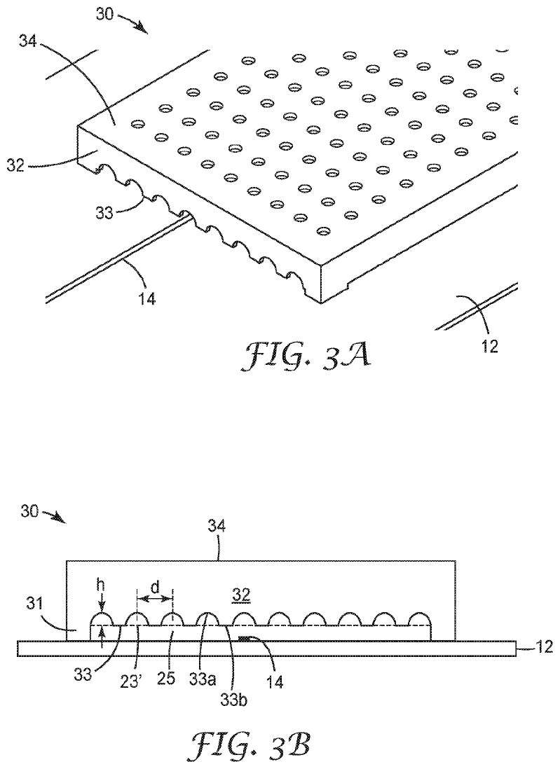

FIG. 3A illustrates a partial perspective view of an EMI shield 30, according to one embodiment. FIG. 3B illustrates a side cross sectional view of the EMI shield 30. The EMI shield 30 is configured to be placed on and cover an electronic component mounted on a circuit board. The electronic component can include, for example, an electrical trace, an electronic device, etc., which can be disposed on a circuit board. For example, the EMI shield 30 can be provided to cover the trace portions 14a of the electrical trace 14 on the PCB 12 in FIG. 1. The EMI shield 30 includes an electrically conductive fence 32 configured to surround the electronic component, and an electrically conductive lid 34 attached to a top side of the fence 32. The fence 32 includes one or more side walls that are substantially perpendicular to the PCB 12. In some embodiments, the conductive lid 34 can be assembled to the fence 32. In some embodiments, the conductive lid 34 and the fence 32 can form a unitary construction. The EMI shield 30 is configured to attenuate an electromagnetic field primarily by reflection. The shield 30 can include any suitable electrically conductive materials such as, for example, metal.

The fence 32 includes corners 31 that can be grounded to the PCB 12 and a bottom edge 33 extending between the corners 31. The bottom edge 33 faces the PCB 12, providing the gap 25 with respect to the PCB 12 to allow the electrical trace 14 fitting therethrough without touching the bottom edge 33. The shield 30 may have the same configuration as the shield 20 in FIG. 2A except for the bottom edge(s) 33. The dashed line 23′ indicates the original position of the straight bottom edge 23 in FIG. 2B that defines the gap 25. Different from the straight bottom edge 23 of FIG. 2B, at least a portion of the bottom edge 33 of the shield 30 is an undulated edge. In the depicted embodiment, the undulated edge 33 includes curved segments 33a and straight segments 33b arranged alternatingly along a length of the edge 33. The curved segments 33a are arc segments. The undulated edge 33 can have a peak to valley height “h”, and a peak to peak or valley to valley distance “d” as shown in FIG. 3B.

In some embodiments, the shield may include an undulated edge (e.g., 33 in FIG. 3B) having a first edge portion (e.g., 33b in FIG. 3B) and a different second edge portion (e.g., 33a in FIG. 3B), such that when the shield is mounted on a circuit board, at least the first edge portion of the undulated edge being spaced apart from the circuit board. The first and second edge portions are arranged along a length of the second edge portion. A side wall has the undulated edge, such that when the shield is mounted on a circuit board, the side wall is substantially perpendicular to the circuit board with the undulated edge facing the circuit board. In some embodiments, an average separation between the first edge portion and the circuit board is less than an average separation between the second edge portion and the circuit board. In some embodiments, an average separation between the first edge portion and the circuit board is at least 2 times less than an average separation between the second edge portion and the circuit board. In some embodiments, an average separation between the first edge portion and the circuit board is at least 1 micron less than an average separation between the second edge portion and the circuit board. In some embodiments, an average separation between the first edge portion and the circuit board is at least 5 microns less than an average separation between the second edge portion and the circuit board.

In some embodiments, when the shield is mounted on a circuit board, the shield is configured to cover an electronic component mounted on the circuit board and the second edge portion is configured to face a signal trace of the circuit board with the undulated portion of the second edge portion extending laterally across the signal trace and on each side of the signal trace.

In some embodiments, the shield further may include a third edge portion (e.g., corners 31 in FIG. 3B) different than the first and second edge portions. The second edge portion is disposed between the third edge portions, such that when the shield is mounted on a circuit board, the third edge portions rest on and contact the circuit board and the first and second edge portions are spaced apart from the circuit board.

The undulated edges described herein are intentionally designed to improve edge discontinuity, and thereby reducing possible edge currents on the shield as discussed above for FIG. 2A. It is to be understood that the undulated edge 33 can have various shapes or patterns. In some embodiments, the undulated edge 33 can include, for example, one or more regular undulations, one or more periodic undulations, one or more sinusoidal undulations, one or more irregular undulations, or any combinations thereof. The undulated edges described herein include undulated shapes or patterns that are different from the inherent roughness on a planar surface such as the straight edge 23 in FIG. 2B.

In some embodiments, the shield 30 is configured to at least partially block electromagnetic radiation having a first wavelength in a range of, for example, about 30 meters to about 0.0075 meters. In some embodiments, the undulated edge 33 can have the average peak to valley height “h” greater than the first wavelength divided by, for example, 20, 50, 100, or 200. In some embodiments, the undulated edge 33 can have an average peak to valley height “h” greater than, for example, about 1 micron, about 5 microns, about 25 microns, or about 0.1 mm. In some embodiments, the average peak to valley height “h” can be in the range of, for example, about 1 micron to about 10 mm, about 5 micron to about 5 mm, or about 10 micron to about 2 mm. The peak to peak or valley to valley distance “d” can be in the range of, for example, 0.1×h to 20×h.

It is to be understood that in the present disclosure, the dimensions (e.g., average peak to valley height “h”, peak to peak or valley to valley distance “d”, etc.) of the undulated edge 33 may depend on the frequency or wavelength of EMI to be shielded. In some embodiments, the larger the wavelength of EMI, the larger dimensions of the undulated edge may be preferred to achieve effective shielding.

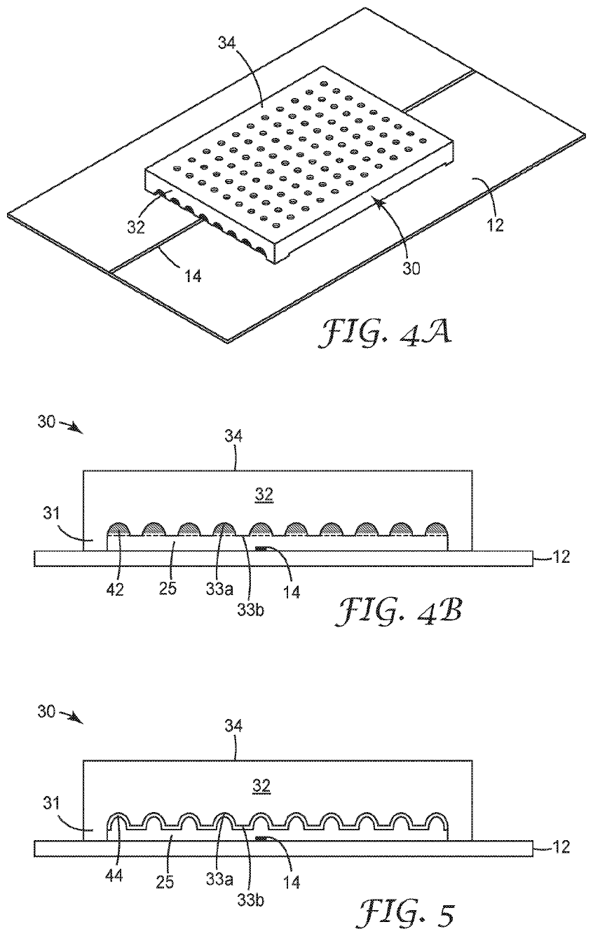

FIG. 4A illustrates a partial perspective view of the EMI shield 30 including an EMI absorbing material 42 disposed on and along at least a portion of the undulated edge 33 of the fence 32. The EMI absorbing material 42 is configured to attenuate an electromagnetic field primarily by absorption. In some embodiments, the EMI absorbing material 42 may include the same or different absorbing material as in the absorbing material 27 in FIG. 2C. In the depicted embodiments, the EMI absorbing material 42 is disposed on the curved segments 33a to at least partially fill the recesses thereof, without reducing the gap 25 between the undulated edge 33 and the PCB 12. In some embodiments, the EMI absorbing material 42 can also be disposed on the straight segments 33b, which might reduce the gap 25 between the undulated edge 33 and the PCB 12. In some embodiments, the EMI absorbing material 42 may not be in direct contact with the PCB 12 to prevent possible short circuit issue. The EMI absorbing material 42 can be provided to the undulated edge 33 by any suitable techniques including, for example, deposition, coating, plating, etc.

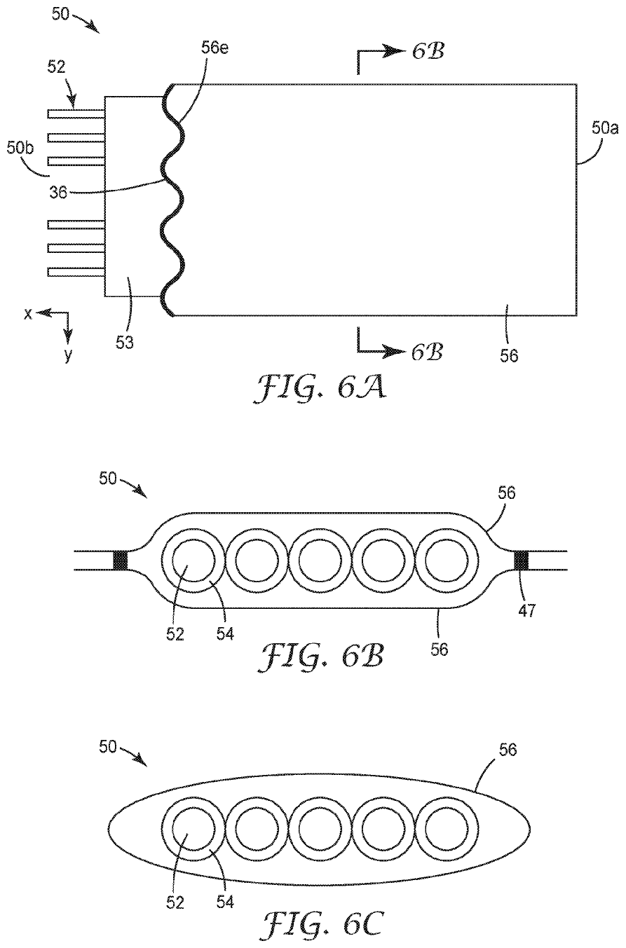

FIG. 5 illustrates a partial perspective view of the EMI shield 30 including a layer 44 of EMI absorbing material disposed on and along at least a portion of the undulated edge 33 of the fence 32. The layer 44 is substantially conformal to the surface of undulated edge 33 and configured to attenuate an electromagnetic field primarily by absorption. The layer 44 can be disposed on the undulated edge 33 by any suitable techniques including, for example, deposition, coating, plating, etc. In some embodiments, the layer 44 may have a thickness which may be, for example, about 0.05 mm or more, about 0.1 mm or more, or about 0.2 mm or more. The thickness may be, for example, about 10 mm or less, about 5 mm or less, or about 2 mm or less. The thickness may be in the range of, for example, about 0.1 mm to about 2 mm.

FIGS. 4A-B and 5 illustrate two forms 42 and 44 of EMI absorbing material disposed on and along the undulated edge 33. It is to be understood that one or more EMI absorbing materials can be applied in various forms onto and along an undulated edge of a shield such as, for example, the undulated edge 33 of the fence 32. The shield includes a first shield portion (e.g., a metallic fence) configured to attenuate an electromagnetic filed (e.g., EMI) by reflection, and a second shield portion (e.g., an EMI absorbing material) configured to attenuate the electromagnetic filed primarily by absorption. The first and second shield portions define an undulated interface therebetween (e.g., the surface interface between the undulated edge 33 and the absorbing material 42 or 44 in FIGS. 4B and 5).

In some embodiments, each of the first and second shield portions includes a minor structured side surface extending between opposing major surfaces. The undulated interface can be a surface interface between the minor structured side surfaces of the first and second shield portions.

In some embodiments, the second shield portion may include another minor side surface opposite the minor structured side surface. The other minor side surface can be substantially smooth or conformal to the minor structure side surface. For example, the absorbing material 42 or 44 in FIGS. 4B and 5 each have an outer surface facing the circuit board 12 which is substantially smooth or conformal to the minor structure side surface.

In some embodiments, the undulated interface has a first average peak to valley height, and the second shield portion includes another minor side surface opposite the minor structured side surface has a second average peak to valley height that may be less than the first average peak to valley height. In some embodiments, the second average peak to valley height may be at least 2 times, or 5 times less than the first average peak to valley height.

In some embodiments, the undulated interface may include a periodic surface. In some embodiments, the first and second shield portions may have substantially equal thicknesses in a thickness direction substantially perpendicular to the length of the undulated edge.

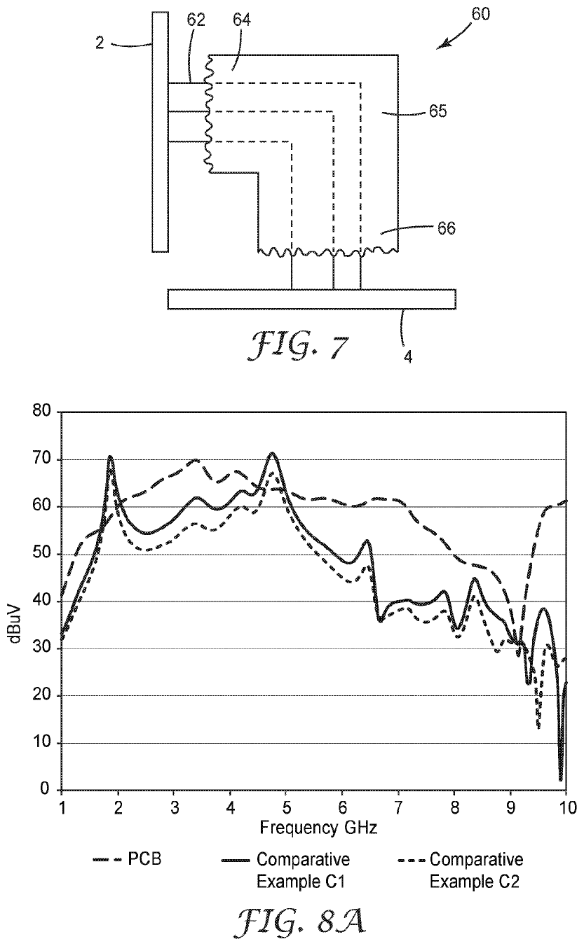

FIG. 6A illustrates a side view of a shielded electrical cable 50, according to one embodiment. The shielded electrical cable 50 extends longitudinally along a length of the cable (e.g., the x axis) between a first end 50a and a second end 50b. The cable 50 includes one or more electrical conductors 52 extending along the length of the cable between the first and second ends 50a and 50b. At least one shield 56 extends along the length of the cable from the first end 50a toward the second end 50b. The shield 56 at least partially surrounds the one or more conductors 52. In the depicted embodiment, an electrical-insulating layer 54 is provided to separate the conductors 52 from the surrounding shield 56. The shield 56 has a first edge 56e which has at least a portion being undulated along a width of the cable (e.g., the y axis). In some embodiments, the undulated edge 56e can include, for example, one or more regular undulations, one or more periodic undulations, one or more sinusoidal undulations, one or more irregular undulations, or any combinations thereof.

In some embodiments such as shown in FIG. 6B, the shield 56 can have a top shield and a bottom shield disposed on opposite sides of the cable 50. The top and bottom shields can be connected by an adhesive 47 along the x axis. The shields can have opposing first edges 56e each being undulated along the length of the first edge. In some embodiments such as shown in FIG. 6C, the shield 56 can have a one-piece structure.

An EMI absorbing material 36 is disposed on and along at least a portion of the undulated edge 56e of the shield 56. The EMI absorbing material 36 is configured to attenuate an electromagnetic field primarily by absorption. In some embodiments, the EMI absorbing material 36 may include the same or different absorbing material as in the absorbing material 27 in FIG. 2C. The EMI absorbing material 56 can be provided to the undulated edge 56e of the shield 56 by any suitable techniques including, for example, deposition, coating, plating, etc.

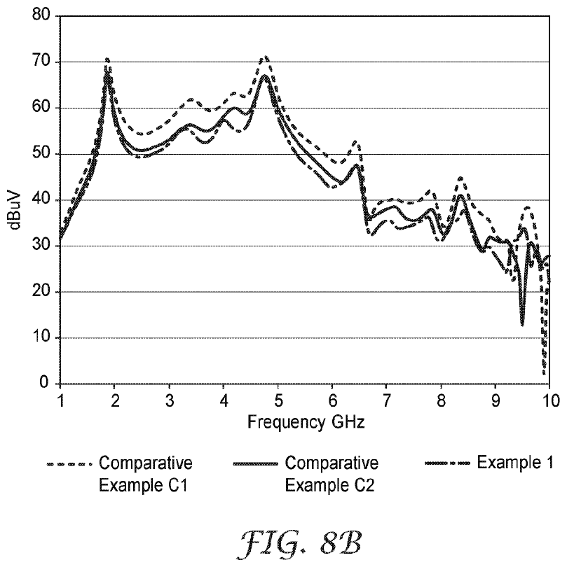

FIG. 7 illustrates a side view of a shielded electrical connector 60 electrically connecting first and second circuit boards 2 and 4. The shielded connector 60 includes one or more electrical conductors 62 at least partially surrounded by the shield 65. The conductors 62 enters the shield 65 from a first undulated edge 64 and exits the shield 65 from a second undulated edge 66. The undulated edges 64 and 66 each can include, for example, one or more regular undulations, one or more periodic undulations, one or more sinusoidal undulations, one or more irregular undulations, or any combinations thereof. In some embodiments, one or more EMI absorbing material can be disposed on and along at least a portion of the undulated edge 64 or 66. The EMI absorbing material can be configured to attenuate an electromagnetic field primarily by absorption. The EMI absorbing material can be provided to at least one of the undulated edges 64 and 66 by any suitable techniques including, for example, deposition, coating, plating, etc.

The present disclosure provides various electromagnetic interference (EMI) shields that include one or more undulated edges. The shields can be provided to at least partially enclose an electronic component such as, for example, an electronic device or trace on a circuit board, an electrical conductor, etc. The undulated edges described herein can help improve the edge discontinuity, thereby reducing any edge currents on the shields. An EMI absorbing material can be disposed on and along the undulated edges to further reduce the induced current.

### LISTING OF EXEMPLARY EMBODIMENTS

It is to be understood that any one of embodiments 1-16, 17-26, 27-33, 34-35, 36-38 and 39-41 can be combined.

Embodiment 1 is an electromagnetic interference (EMI) shield configured to be placed on and cover an electronic component mounted on a circuit board, the EMI shield comprising an electrically conductive fence configured to at least partially surround the electronic component, and an electrically conductive lid attached to a first edge of the fence, the fence having an undulated edge extending along at least a portion of a second edge of the fence opposite the first edge.

Embodiment 2 is the shield of embodiment 1 configured to attenuate an electromagnetic field primarily by reflection.

Embodiment 3 is the shield of embodiment 2 further comprising an EMI absorbing material disposed on and along at least a portion of the undulated edge of the fence, the EMI absorbing material configured to attenuate an electromagnetic field primarily by absorption.

Embodiment 4 is the shield of any one of embodiments 1-3, wherein the conductive lid is assembled to the fence.

Embodiment 5 is the shield of any one of embodiments 1-4, wherein the conductive lid and the fence form a unitary construction.

Embodiment 6 is the shield of any one of embodiments 1-5, wherein the undulated edge comprises regular undulations.

Embodiment 7 is the shield of any one of embodiments 1-6, wherein the undulated edge comprises periodic undulations.

Embodiment 8 is the shield of embodiment 7, wherein the undulated edge comprises sinusoidal undulations.

Embodiment 9 is the shield of embodiment 7, wherein the undulated edge comprises alternating straight and curved segments.

Embodiment 10 is the shield of embodiment 9, wherein the curved segments are arc segments.

Embodiment 11 is the shield of any one of embodiments 1-5, wherein the undulated edge comprises irregular undulations.

Embodiment 12 is the shield of any one of embodiments 1-11 configured to at least partially block electromagnetic radiation having a first wavelength, the undulated edge having an average peak to valley height greater than the first wavelength divided by 200.

Embodiment 13 is the shield of any one of embodiments 1-12 configured to at least partially block electromagnetic radiation having a first wavelength, the undulated edge having an average peak to valley height greater than the first wavelength divided by 100.

Embodiment 14 is the shield of any one of embodiments 1-13 configured to at least partially block electromagnetic radiation having a first wavelength, the undulated edge having an average peak to valley height greater than the first wavelength divided by 50.

Embodiment 15 is the shield of any one of embodiments 1-14, wherein the undulated edge has an average peak to valley height greater than about 1 micron.

Embodiment 16 is the shield of any one of embodiments 1-15, wherein the undulated edge has an average peak to valley height greater than about 5 microns.

Embodiment 17 is an electromagnetic interference (EMI) shield configured to be mounted on a circuit board, the shield comprising an undulated edge having a first edge portion and a different second edge portion, such that when the shield is mounted on a circuit board, at least the first edge portion of the undulated edge being spaced apart from the circuit board, the first and second edge portions being arranged along a length of the second edge portion.

Embodiment 18 is the EMI shield of embodiment 17 comprising a side wall having the undulated edge, such that when the shield is mounted on a circuit board, the side wall is substantially perpendicular to the circuit board with the undulated edge facing the circuit board.

Embodiment 19 is the EMI shield of embodiment 17 or 18, wherein an average separation between the first edge portion and the circuit board is less than an average separation between the second edge portion and the circuit board.

Embodiment 20 is the EMI shield of embodiment 19, wherein an average separation between the first edge portion and the circuit board is at least 2 times less than an average separation between the second edge portion and the circuit board.

Embodiment 21 is the EMI shield of any one of embodiments 17-20, wherein an average separation between the first edge portion and the circuit board is at least 1 micron less than an average separation between the second edge portion and the circuit board.

Embodiment 22 is the EMI shield of embodiment 21, wherein an average separation between the first edge portion and the circuit board is at least 5 microns less than an average separation between the second edge portion and the circuit board.

Embodiment 23 is the EMI shield of any one of embodiments 17-22, such that when the shield is mounted on a circuit board, the shield is configured to cover an electronic component mounted on the circuit board and the second edge portion is configured to face a signal trace of the circuit board with the undulated portion of the second edge portion extending laterally across the signal trace and on each side of the signal trace.

Embodiment 24 is the EMI shield of any one of embodiments 17-23 further comprising a third edge portion different than the first and second edge portions, the second edge portion disposed between the third edge portions, such that when the shield is mounted on a circuit board, the third edge portions rest on and contact the circuit board and the first and second edge portions are spaced apart from the circuit board.

Embodiment 25 is the EMI shield of any one of embodiments 17-24 further comprising an EMI absorbing material disposed on and along the second edge portion, a first edge of the EMI absorbing material disposed on and substantially conforming to the undulations of the second edge portion, and an opposite second edge of the EMI absorbing material being substantially smooth or conformal to the first edge of the EMI absorbing material.

Embodiment 26 is the EMI shield of any one of embodiments 17-25 further comprising a layer of EMI absorbing material disposed on and along the undulated edge.

Embodiment 27. An electromagnetic interference (EMI) shield configured to be placed on and cover an electronic component mounted on a circuit board, the shield comprising:
a first shield portion configured to attenuate an electromagnetic field primarily by reflection; and
a second shield portion configured to attenuate an electromagnetic field primarily by absorption, the first and second shield portions defining an undulated interface therebetween.

Embodiment 28 is the shield of embodiment 27, wherein each of the first and second shield portions comprises a minor structured side surface extending between opposing major surfaces, the undulated interface being a surface interface between the minor structured side surfaces of the first and second shield portions.

Embodiment 29 is the shield of embodiment 28, wherein the second shield portion comprises another minor side surface opposite the minor structured side surface, the other minor side surface being substantially smooth or conformal to the minor structured side surface.

Embodiment 30 is the shield of embodiment 28 or 29, wherein the undulated interface has a first average peak to valley height, and wherein the second shield portion comprises another minor side surface opposite the minor structured side surface having a second average peak to valley height that is less than the first average peak to valley height.

Embodiment 31 is the shield of embodiment 30, wherein the second average peak to valley height that is at least 2 times less than the first average peak to valley height.

Embodiment 32 is the shield of any one of embodiments 27-31, wherein the undulated interface comprises a periodic surface.

Embodiment 33 is the shield of any one of embodiments 27-32, wherein the first and second shield portions have substantially equal thicknesses.

Embodiment 34 is a shielded circuit board system comprising:
a circuit board;
an electronic component mounted on the circuit board and electrically connected to an electrically conductive first signal trace of the circuit board; and
an electromagnetic interference (EMI) shield placed on and covering the electronic component, the first signal trace crossing under an edge of the shield and on each side of the shield to define an overlap region therebetween, a separation between the edge of the shield and the first signal trace being non-uniform across the overlap region.

Embodiment 35 is the shielded circuit board system of embodiment 34, wherein the non-uniform separation is smaller at a first end of the overlap region and greater at an opposite second end of the overlap region.

Embodiment 36 is a shielded cable extending longitudinally along a length of the cable between first and second ends of the cable and comprising:
one or more conductors extending along the length of the cable between the first and second ends; and
at least one shield extending along the length of the cable from the first end toward the second end, the shield having a first edge at least partially surrounding the one or more conductors at the first end, the first edge being regularly undulated along a length of the first edge.

Embodiment 37 is the shielded cable of embodiment 36, wherein the regularly undulated first edge comprises periodic undulations.

Embodiment 38 is the shielded cable of embodiment 36 or 37, wherein the at least one shield comprises opposing first and second shields disposed on opposite sides of the shielded cable, such that, in combination, the first and second shields having opposing first edges at the first end, each first edge being regularly undulated along a length of the first edge.

Embodiment 39 is a shielded electrical connector comprising:
one or more electrical conductors extending between a first end and a second end thereof;
an EMI shield including a first undulated edge adjacent to the first end of the electrical conductors and a second undulated edge adjacent to the second end of the electrical conductors,
wherein the EMI shield at least partially surrounds the electrical conductors to provide EMI protection, and the first and second undulated edges are laterally across the electrical conductors at the first and second ends, respectively.

Embodiment 40 is the shield connector of embodiment 39, further comprising one or more EMI absorbing materials disposed on and along at least one of the first and second undulated edges.

Embodiment 41 is the shield connector of embodiment 39 or 40, wherein the first and second ends of the electrical conductors are configured to electrically connect to one or more circuit boards.

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### EXAMPLES

These Examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Comparative Example C1

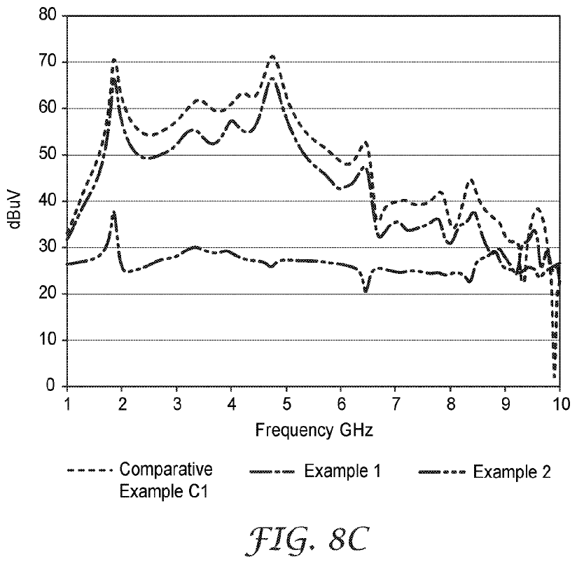

Comparative Example C1 is a metallic shield placed on a PCB with a configuration the same as shown in FIG. 2A. The shield in this example has the dimensions of 75 mm×100 mm and can be prepared using any high conductivity material such as copper, silver, gold, phosphor-bronze, etc. The metallic shield was placed on a PCB with a 2 mm wide trace. The PCB is supported by a 27 mils thick Rogers RT/Duroid 5880 substrate commercially available from Rogers Corporation (Rogers, Conn.) with a solid ground plane on the bottom side. The trace has a small gap in the middle portion thereof. The metallic shield was placed to enclose the middle portion of the trace. An induced voltage due to an external EMI was calculated. The external EMI propagates towards the PCB as a plane wave and impinges upon the PCB at a normal incidence angle. The resulting induced voltage is shown in FIG. 8A. The metallic shield of C1 can provide shielding protection by reducing the induced voltage in some frequency regions, but fails to decrease the induced voltage at least in some low frequency regions.

### Comparative Example C2

Comparative Example C2 is a metallic shield placed on a PCB with a configuration the same as shown in FIG. 2C. C2 is the same as C1 except that an EMI absorbing material was placed on the top of the metallic shield. The absorbing material was a one mm thick dielectric absorbing material with dielectric permittivity of 6 and loss tangent of 0.5. An induced voltage due to an external EMI was calculated. The external EMI propagates towards the PCB as a plane wave and impinges upon the PCB at a normal incidence angle. The resulting induced voltage is shown in FIG. 8A. The application of EMI absorbing material on the metallic shield in C2 provided minor improvement over C1 in terms of shielding effectiveness.

### Example 1

Example 1 is an EMI shield placed on a PCB with a configuration the same as shown in FIG. 3A. The metallic shield of Example 1 is the same as that in C1 except for an undulated edge having wave-like variations. Such shape helped improve the edge discontinuity, thereby reducing the edge currents on the shield. An induced voltage due to an external EMI was calculated. The external EMI propagates towards the PCB as a plane wave and impinges upon the PCB at a normal incidence angle. The resulting induced voltage is shown in FIG. 8B as the curve 804. The EMI shield of Example 1 provided a slight improvement in terms of shielding effectiveness over the metallic shields of C1 and C2. In Example 1, the space between the undulated edge and the circuit board is greater that the space between in the straight edge and the circuit board in C1 and C2. See FIGS. 2B and 3B. While not want to be bound by theory, it is believed that the improved shielding effects is due to the undulated edge.

### Example 2

Example 2 is an EMI shield placed on a PCB with a configuration the same as shown in FIG. 4A. The metallic shield of Example 2 is the same as that in Example 1 except that an EMI absorbing material was disposed on and along the undulated edge of the shield. An induced voltage due to an external EMI was calculated. The external EMI propagates towards the PCB as a plane wave and impinges upon the PCB at a normal incidence angle. The resulting induced voltage is shown in FIG. 8C as the curve 805. The EMI shield of Example 2 provided a significant improvement in terms of shielding effectiveness over the metallic shield of C1.

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.”

Furthermore, all publications and patents referenced herein are incorporated by reference in their entirety to the same extent as if each individual publication or patent was specifically and individually indicated to be incorporated by reference. Various exemplary embodiments have been described. These and other embodiments are within the scope of the following claims.

1. An electromagnetic interference (EMI) shield configured to be placed on and cover an electronic component mounted on a circuit board, the EMI shield comprising:
an electrically conductive fence configured to at least partially surround the electronic component;
an electrically conductive lid attached to a first edge of the fence, the fence having an undulated edge extending along at least a portion of a second edge of the fence opposite the first edge; and
an EMI absorbing material disposed on and along at least a portion of the undulated edge of the fence, the EMI absorbing material configured to attenuate an electromagnetic field primarily by absorption.

2. The shield of claim 1 configured to attenuate an electromagnetic field primarily by reflection.

3. (canceled)

4. The shield of claim 1, wherein the undulated edge comprises regular undulations.

5. The shield of claim 1, wherein the undulated edge comprises periodic undulations.

6. The shield of claim 5, wherein the undulated edge comprises sinusoidal undulations.

7. The shield of claim 5, wherein the undulated edge comprises alternating straight and curved segments.

8. The shield of claim 7, wherein the curved segments are arc segments.

9. The shield of claim 1 configured to at least partially block electromagnetic radiation having a first wavelength, the undulated edge having an average peak to valley height greater than the first wavelength divided by 200.

10. An electromagnetic interference (EMI) shield configured to be placed on and cover an electronic component mounted on a circuit board, the shield comprising:
a first shield portion configured to attenuate an electromagnetic field primarily by reflection; and
a second shield portion configured to attenuate an electromagnetic field primarily by absorption, the first and second shield portions defining an undulated interface therebetween.

11. The shield of claim 10, wherein each of the first and second shield portions comprises a minor structured side surface extending between opposing major surfaces, the undulated interface being a surface interface between the minor structured side surfaces of the first and second shield portions.

12. The shield of claim 11, wherein the undulated interface has a first average peak to valley height, and wherein the second shield portion comprises another minor side surface opposite the minor structured side surface having a second average peak to valley height that is less than the first average peak to valley height.

13. The shield of claim 12, wherein the second average peak to valley height that is at least 2 times less than the first average peak to valley height.

14. The shield of claim 10, wherein the undulated interface comprises a periodic surface.

15. The shield of claim 10, wherein the first and second shield portions have substantially equal thicknesses.

16. A shielded cable extending longitudinally along a length of the cable between first and second ends of the cable and comprising:
one or more conductors extending along the length of the cable between the first and second ends; and
at least one shield extending along the length of the cable from the first end toward the second end, the shield having a first edge at least partially surrounding the one or more conductors at the first end, the first edge being regularly undulated along a length of the first edge.

17. The shielded cable of claim 16, wherein the regularly undulated first edge comprises periodic undulations.

18. The shielded cable of claim 16, wherein the at least one shield comprises opposing first and second shields disposed on opposite sides of the shielded cable, such that, in combination, the first and second shields having opposing first edges at the first end, each first edge being regularly undulated along a length of the first edge.

19. A shielded electrical connector comprising:
one or more electrical conductors extending between a first end and a second end thereof;
an EMI shield including a first undulated edge adjacent to the first end of the electrical conductors and a second undulated edge adjacent to the second end of the electrical conductors, wherein the EMI shield at least partially surrounds the electrical conductors to provide EMI protection, and the first and second undulated edges are laterally across the electrical conductors at the first and second ends, respectively.

20. The shield electrical connector of claim 19, further comprising one or more EMI absorbing materials disposed on and along at least one of the first and second undulated edges.

21. The shield electrical connector of claim 19, wherein the first and second ends of the electrical conductors are configured to electrically connect to one or more circuit boards.
